(19) United States
(12) Patent Application Publication
(10) Pub. No.: US 2007/0264780 A1
(43) Pub. Date: Nov. 15, 2007

(54) Method of fabricating a vertical nano-transistor

(76) Inventors: Jie Chen, Berlin (DE); Martha Christina Lux-Steiner, Berlin (DE)

Correspondence Address: Law Offices of Karl Hormann, P.O. Box 381516, Cambridge, MA, 02238-1516, US

(21) Appl. No.: 11/879,435

(22) Filed: Jul. 17, 2007

Related U.S. Application Data
(62) Division of application No. 10/568,230, filed on Feb. 11, 2006.

(30) Foreign Application Priority Data
Aug. 21, 2003 (DE) DE 103 39 531.8

(51) Int. Cl. H01L 21/336

(52) U.S. Cl. 438/268; 257/E21.409

(57) ABSTRACT

A method of fabricating a vertical nano-transistor by forming holes in a thin metal film to provide the gate region for forming the channel region, applying insulation material to the walls of the holes and to the upper and lower surface of the metal film, applying semiconductor material in the insulated holes for forming the semiconductor channel region, and applying contacts for forming the source and drain regions.

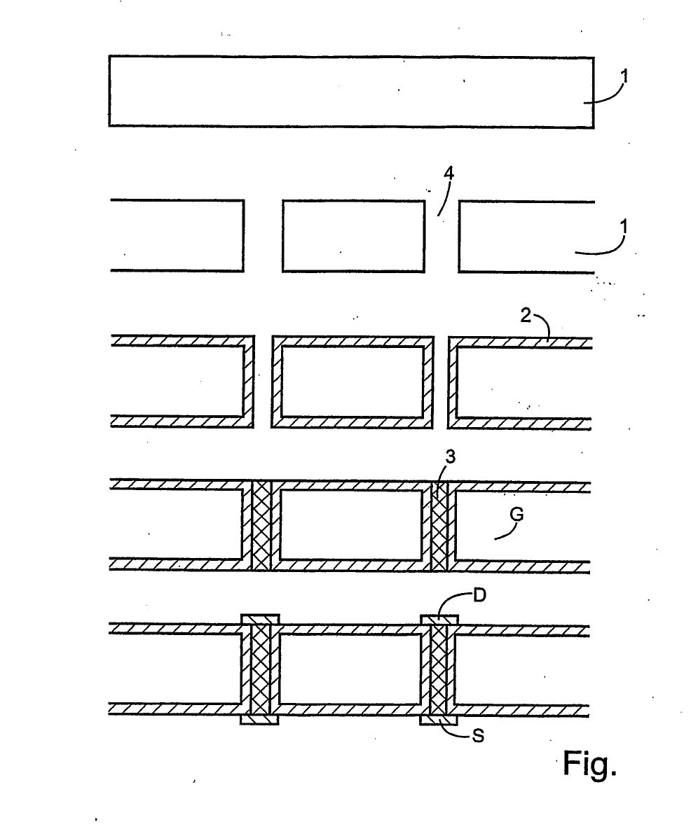

### REFERENCE TO RELATED APPLICATIONS.

The present application is a division of currently pending U.S. patent application Ser. No. 10/568,230 filed 11 Feb. 2006.

### BACKGROUND OF THE INVENTION

1. Field of the Invention

The invention, in general, relates to a vertical nano-transistor and, more particularly, to a novel method of its fabrication.

2. The Prior Art

German laid-open patent specification DE-OS 101 42 913 describes a transistor arrangement which resists mechanical stresses caused by bending, shearing or stretching, in which semiconductor material is vertically introduced into micro-holes of a film composite consisting of plastic films with an intermediate metal layer. The semiconductor material is provided with metallic contacts at the upper and lower surfaces of the film composite. However, the application of a metal layer on a plastic film is no easy matter. Moreover, the method of fabricating a vertical transistor arrangement of this type includes a plurality of individual method steps.

The fabrication of a vertical nano-transistor described by US 2002/0001905 is also complex and complicated, since initially a source region is applied to an expensive semiconductor substrate which is not flexible and onto which an insulating layer is applied. Holes in the nm-range are provided in the insulating layer (Al₂O₃ or Si), and vertically aligned carbon nano-tubes are inserted into these holes. The gate region is arranged above the insulating layer around the carbon nano-tubes and is filled with a non-conductive material up to the upper cover surface of the nano-tubes. Forming the gate region around the nano-tubes and maintaining identical diameters of these nano-tubes during filling has proved to be very difficult, and may result in vertical transistor arrangements which because of the different diameters of the relevant nano-tubes are of different characteristics.

### OBJECT OF THE INVENTION

It is, therefore, an object of the invention to provide a novel method of fabricating a vertical nano-transistor capable of resisting mechanical stresses, and which is of lower complexity than what has hitherto been known in the prior art. A memory assembly is to be provided as well.

### SUMMARY OF THE INVENTION

In accordance with the invention, the object is accomplished by a method of fabricating a vertical nano-transistor provided with a source region, a drain region, a gate region and a semiconductor channel region between the source region and the drain region, wherein the gate region is formed by the steps of embedding the transistor in a metal film such that the gate region and the semiconductor channel region form a coaxial structure and of vertically arranging the source region, the semiconductor channel region and the drain region being arranged and of electrically insulating the gate region from the source region, the drain region and the semiconductor channel region.

In the system in accordance with the invention, the gate region is formed by an extremely thin metal film. The otherwise extremely difficult application of a metal layer onto a plastic film is avoided; also, unlike in the mentioned prior art arrangement, individual films need not be assembled into a composite film. The density of the holes formed in the metal film for providing the coaxial structures is very high.

Embodiments of the invention provide for cylindrically structuring the semiconductor channel region. The diameter of the semiconductor channel region amounts to from several ten to several hundred nanometers. The material of the semiconductor channel region is CuSCN or TiO₂ or PbS or ZnO or another compound semiconductor.

The thickness of the metal film forming the vertical gate region is less than 100 μm, preferably 5 to 20 μm. Compared to plastic film, the height of the metal film is more uniform which, given the small thickness, ensures that the inserted holes do indeed penetrate through the film. Moreover, as a result of the very thin metal film, the system according to the invention is highly resistant against mechanical stresses.

In another embodiment the thickness of the electrical insulation in the channel region amounts to several to several hundred nanometers. The thickness of the insulation layer at the upper and lower surfaces of the metal film amounts to several micrometers. The insulation layer may be applied by known processes of thin-film technology.

The material of the source and for the drain regions is Au or Ag or Cu or Ni or Al. The source and drain region may be structured as dots.

The system in accordance with the invention also includes a memory arrangement consisting of a plurality of the inventive vertical nano-transistors arranged adjacent each other on the metal film.

Preferably, the method in accordance with the invention of fabricating the novel vertical nano-transistor consists of, but is not limited to, the steps of forming holes in a thin metal film constituting the gate region of the transistor for providing the channel region, applying a coating of insulating material to the walls of the holes, applying insulating material on the upper and lower surface of the metal film, inserting semi-conductor material into the coated holes for forming the semi-conductor channel region and of applying contacts for forming the source and drain regions.

In preferred embodiments of the method in accordance with the invention the holes in the metal foil are formed by focused ion beams or by laser beams.

The insulating material is applied by thin-film technology or by vacuum filtration of a polymeric solution onto the wall of the holes and onto the upper and lower surface of the metal film.

In other embodiments of the invention the semi-conductor material which may be CuSCN or TiO₂ or PbS or ZnO or another compound semi-conductor is introduced into the holes of the metal foil by electro-chemical bath precipitation, by chemical deposition or by the ILGAR process.

The method of fabricating the vertical nano-transistor arrangement in accordance with the invention is simple and adapts to the known thin-film technologies. As a result of the arrangement in accordance with the invention the method of fabrication is no longer limited to predetermined temperatures.

### DESCRIPTION OF THE DRAWING

The novel features which are considered to be characteristic of the invention are set forth with particularity in the appended claims. The invention itself, however, in respect of its structure, construction and lay-out, as well as manufacturing techniques, together with other objects and advantages thereof, will be best understood from the following description when read with reference to the drawing.

The drawing depicts the fabrication steps of vertical nano-transistors in accordance with the invention which are embedded in a metal film.

### DETAILED DESCRIPTION OF THE PREFERRED EMBODIMENT

Initially, holes 4 of a diameter of 200 nm are formed by laser irradiation in an Al or Cu film of 30 μm thickness. Thereafter, an insulation layer 2 of organic material, e.g. Al₂O₃, ZnS, SiO₂ or inorganic material, e.g. polystyrene, is applied to the wall of the holes 4 by vacuum filtration of a polymer solution. The thickness of this layer 2 is 50 nm. Thereafter, an insulation layer 2 of a thickness of several micrometers is also applied to the upper and lower surface of the metal film 1 by known thin-film technologies. Following this, the insulated holes 4 in the metal film 1 are filled with CuSCN. This concludes the formation of a semi-conductor channel region 3 of a diameter of 100 nm. As a final step, metallic contacts are applied as drain D and source S contacts.

What is claimed is:

1. A method of fabricating a vertical nano-transistor, comprising the steps of:
forming holes in a thin metal film constituting the gate region of the transistor, for forming the channel region,
coating the walls of the holes with insulation material,
applying insulation material to the upper and lower surface of the metal film,
filling the insulated holes with semiconductor material for forming the semiconductor channel region,
applying contacts for forming the source and drain regions.

2. The method of claim 1,
wherein the holes are formed in the metal film by focused ion beams.

3. The method of claim 1,
wherein the holes are formed in the metal film by a laser beam.

4. The method of claim 1,
wherein the insulation material is applied to the upper and lower surface of the metal film by thin-film technology.

5. The method of claim 1,
wherein the insulation material is applied to the wall of the holes and to the upper and lower surface of the metal film by vacuum filtration of a polymer solution.

6. The method of claim 1,
wherein the insulation material is applied to the wall of the holes and to the upper and lower surface of the metal foil by electrochemical deposition.

7. The method of claim 1,
wherein the insulation material is applied to the wall of the holes and to the upper and lower surface of the metal foil by chemical deposition.

8. The method of claim 1,
wherein the semiconductor channel region is formed with a material selected from the group consisting of CuSCN, TiO₂, PbS, ZnO and another compound semiconductor.

9. The method of claim 1,
wherein the semiconductor material is introduced into the insulated holes by electrochemical bath precipitation.

10. The method of claim 1,
wherein the semiconductor material is introduced into the insulated holes by chemical deposition.

11. The method of claim 1,
wherein the semiconductor material is introduced into the insulated holes by the ILGAR process.

12. The method of claim 1,
wherein the source and drain regions comprise a material selected from the group consisting of Au, Ag, Cu, Ni and Al.
